(19) United States
(12) Patent Application Publication
(10) Pub. No.: US 2026/0076071 A1
(43) Pub. Date: Mar. 12, 2026

(54) DISPLAY APPARATUS

(71) Applicant: Samsung Display Co., Ltd., Yongin-Si (KR)

(72) Inventors: Ohjune Kwon, Yongin-si (KR); Wooyong Sung, Yongin-si (KR)

(21) Appl. No.: 19/252,985

(22) Filed: Jun. 27, 2025

(30) Foreign Application Priority Data
Jul. 4, 2024 (KR) 10-2024-0088506

(51) Int. Cl. H10K 59/80; H10K 59/40

(52) U.S. Cl. CPC H10K 59/873; H10K 59/40

(57) ABSTRACT

A display apparatus includes a display area, a peripheral area located outside the display area and including sides and a corner peripheral area that is located between two of the sides that extend in different directions, a display element located in the display area, a first dam portion located in the peripheral area and arranged to surround the display area, and a pattern group located in the corner peripheral area such that the first dam portion is between the display area and the pattern group, wherein the pattern group includes a first pattern portion including a plurality of patterns spaced apart from each other along a radial direction.

### CROSS-REFERENCE TO RELATED APPLICATION

This application is based on and claims priority under 35 U.S.C. § 119 to Korean Patent Application No. 10-2024-0088506 filed on Jul. 4, 2024 in the Korean Intellectual Property Office, the disclosure of which is incorporated by reference herein in its entirety.

### BACKGROUND

### 1. Field

One or more embodiments relate to a display apparatus.

### 2. Description of the Related Art

Recently, designs of display apparatuses have become increasingly diverse. For example, curved surface-type display apparatuses, foldable display apparatuses, and rollable display apparatuses have been developed. The design trend appears to involve enlarging a display area and reducing a non-display area. Accordingly, various methods have been developed to design the shapes of display apparatuses.

### SUMMARY

One or more embodiments include a display apparatus having rounded corners.

Additional aspects will be set forth in part in the description which follows and, in part, will be apparent from the description, or may be learned by practice of the presented embodiments of the disclosure.

According to one or more embodiments, a display apparatus includes a display area, a peripheral area located outside the display area and including sides and a corner peripheral area that is curved and located between two of the sides that extend in different directions, a display element located in the display area, a first dam portion located in the peripheral area and arranged to surround the display area, and a pattern group located in the corner peripheral area such that the first dam portion is between the display area and the pattern group, wherein the pattern group may include a first pattern portion including a plurality of patterns spaced apart from each other along a radial direction.

In an embodiment, the pattern group may further include a second pattern portion including a plurality of patterns spaced apart from each other in the radial direction, and the second pattern portion may be spaced apart from the first pattern portion along the circumferential direction of the corner peripheral area.

In an embodiment, corresponding parts of a pattern among the plurality of patterns of the first pattern portion and a pattern among the plurality of patterns of the second pattern portion may be non-parallel.

In an embodiment, the pattern group may further include a third pattern portion located between the first pattern portion and the second pattern portion and including at least one pattern, and in a plan view, patterns of the first pattern portion, the second pattern portion, and the third pattern portion may form a curved checkerboard of with pattern-free areas.

In an embodiment, each of the plurality of patterns of the first pattern portion may be a wave shaped pattern extending along the circumferential direction of the corner peripheral area.

In an embodiment, each of the plurality of patterns in the first pattern portion may be an embossed pattern.

In an embodiment, each of the plurality of patterns in the first pattern portion may be an engraved pattern.

In an embodiment, the display apparatus may further include a second dam portion located in the peripheral area and surrounding the display area, wherein the second dam portion may be located between the pattern group and the first dam portion.

In an embodiment, the display apparatus may further include a crack prevention dam located in the peripheral area and surrounding the display area, wherein the pattern group may be located between the first dam portion and the crack prevention dam.

In an embodiment, the display apparatus may further include an encapsulation layer that encapsulates the display element in the display area and includes at least one inorganic encapsulation layer and at least one organic encapsulation layer, wherein the at least one organic encapsulation layer may extend from the display area to the first dam portion located in the peripheral area.

In an embodiment, the organic encapsulation layer may not overlap with the pattern group.

In an embodiment, the at least one inorganic encapsulation layer may extend from the display area to the peripheral area, be disposed on the first dam portion and under the first pattern portion.

In an embodiment, the display apparatus may further include a touch sensor layer disposed on the encapsulation layer in the display area, wherein the touch sensor layer may include a first touch conductive layer, a second touch conductive layer disposed on the first touch conductive layer, a touch insulating layer between the first touch conductive layer and the second touch conductive layer, and a passivation layer disposed on the second touch conductive layer, wherein the passivation layer may extend from the display area to the peripheral area and be disposed on the plurality of patterns of the first pattern portion.

In an embodiment, each of the plurality of patterns of the first pattern portion may include a same material as the touch insulating layer.

According to one or more embodiments, a display apparatus includes a display area, a peripheral area located outside the display area and including sides and a corner peripheral area that is curved and located between two of the sides that extend in different directions, a display element located in the display area, a first dam portion located in the peripheral area and arranged to surround the display area, and a pattern group located in the corner peripheral area such that the first dam portion is between the display area and the pattern group, wherein the pattern group may include a first pattern portion and a second pattern portion spaced apart from each other along the circumferential direction of the corner peripheral area, and each of the first pattern portion and the second pattern portion may include at least one pattern.

In an embodiment, the pattern group may further include a third pattern portion located between the first pattern portion and the second pattern portion and including at least one pattern, and in a plan view, patterns of the first pattern portion, the second pattern portion, and the third pattern portion may form a curved checkerboard with pattern-free areas.

In an embodiment, the at least one pattern of each of the first pattern portion and the second pattern portion may be an embossed pattern.

In an embodiment, the at least one pattern of each of the first pattern portion and the second pattern portion may be an engraved pattern.

In an embodiment, the display apparatus may further include a second dam portion located in the peripheral area and surrounding the display area, wherein the second dam portion may be located between the pattern group and the first dam portion.

In an embodiment, the display apparatus may further include an encapsulation layer that encapsulates the display element in the display area and includes at least one inorganic encapsulation layer and at least one organic encapsulation layer, wherein the organic encapsulation layer may extend from the display area to the first dam portion located in the peripheral area, and the inorganic encapsulation layer may extend from the display area to the peripheral area, be disposed on the first dam portion and under the first pattern portion.

According to one or more embodiments, an electronic apparatus includes a display apparatus, wherein the display apparatus may include a display area, a peripheral area located outside the display area and including sides and a corner peripheral area that is curved and located between two of the sides that extend in different directions, a display element located in the display area, a first dam portion located in the peripheral area and arranged to surround the display area, and a pattern group located in the corner peripheral area such that the first dam portion is between the display area and the pattern group, wherein the pattern group may include a first pattern portion including a plurality of patterns spaced apart from each other along a radial direction.

In an embodiment, the electronic apparatus may include one of a smart phone, a tablet PC, a laptop, a TV, a desk monitor, smart glasses, a head mounted display, a smart watch, and a vehicle electronic device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is a schematic plan view of a display apparatus according to an embodiment, which corresponds to an enlarged plan view of the region E of FIG. 1;

FIG. 3 is a schematic cross-sectional view of a display apparatus according to an embodiment, taken along line I-I′ of FIG. 2;

FIG. 4 is a schematic plan view of a display apparatus according to an embodiment, which corresponds to an enlarged plan view of the region E of FIG. 1;

FIG. 5 is a schematic plan view of a display apparatus according to an embodiment, which corresponds to an enlarged plan view of the region E of FIG. 1;

FIG. 6 is a schematic plan view of a display apparatus according to an embodiment, which corresponds to an enlarged plan view of the region E of FIG. 1;

FIG. 7 is a schematic plan view of a display apparatus according to an embodiment, which corresponds to an enlarged plan view of the region E of FIG. 1; and

FIG. 8 is a block diagram of an electronic apparatus according to an embodiment.

FIG. 9 is a schematic diagrams of electronic apparatuses according to various embodiments.

### DETAILED DESCRIPTION

One or more embodiments may be modified in various ways and thus, specific embodiments are illustrated in the drawings and described in detail. Effects and features of one or more embodiments and methods for achieving the same could become clear by referring to embodiments described in detail below along with the drawings. However, one or more embodiments are not limited to the embodiments described below and may be implemented in various forms.

Hereinbelow, one or more embodiments are described in detail with reference to the accompanying drawings. When describing with reference to the drawings, identical or corresponding elements are assigned the same reference characters, and redundant descriptions thereof are omitted.

Herein, terms such as “first” and “second” are used not in a limiting sense but for the purpose of distinguishing one element from another element.

Herein, singular expressions include plural expressions, unless the context clearly dictates otherwise.

Herein, terms such as “comprise,” “include,” or “have” mean the presence of features or elements described in the specification, and do not preclude the possibility of adding one or more other features or elements.

Herein, when a part of a film, area, element, or the like is disposed above or on another part, it refers not only to a case where the part is directly on top of the other part, but also a case where another film, area, element, or the like is located therebetween.

In the drawings, for convenience of description, the sizes of elements may be exaggerated or reduced. For example, the size and thickness of each element shown in the drawings are shown arbitrarily for convenience of description, and thus, one or more embodiments are not necessarily limited to the illustrations.

In cases where an embodiment may be implemented differently, a specific process sequence may be performed differently from the described sequence. For example, two processes described in succession may be performed substantially at the same time, or may be performed in an order opposite to that in which they are described.

Herein, “A and/or B” indicates A, B, or A and B. In addition, “at least one of A or B” indicates A, B, or A and B.

Herein, when films, areas, elements, or the like are described to be connected, it includes a case where the films, the areas, the elements, or the like are directly connected, or/and a case where the films, the areas, the elements, or the like are indirectly connected with other films, areas, or elements therebetween. For example, herein, when it is described that films, areas, elements, or the like are electrically connected, it indicates a case where the films, areas, elements, or the like are directly electrically connected, or/and a case where the films, areas, the elements, or the like are indirectly electrically connected with other films, areas, or elements therebetween.

An x-axis, a y-axis, and a z-axis are not limited to the three axes in the Cartesian coordinate system, but may be interpreted in a broad sense including the same. For example, the x-axis, y-axis, and z-axis may be orthogonal to each other, but may also refer to different directions that are not orthogonal to each other.

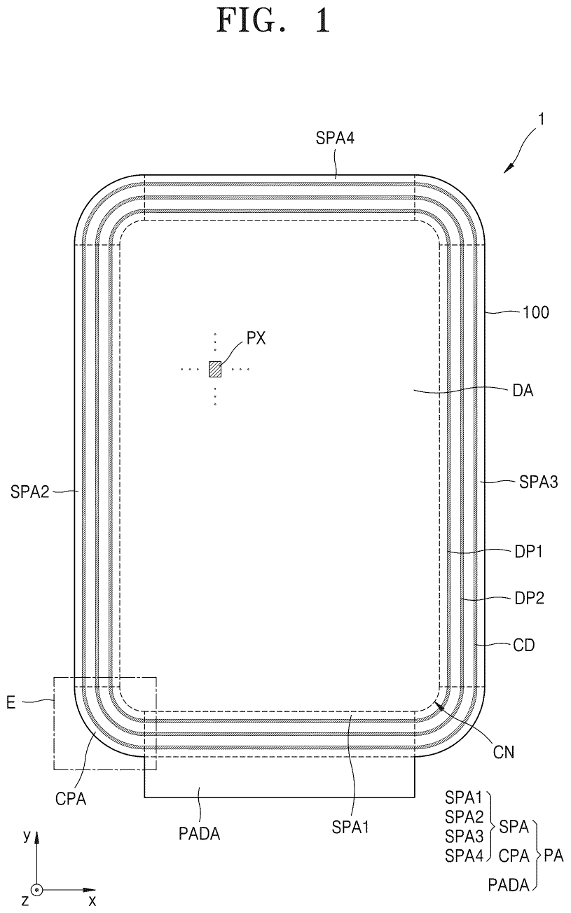

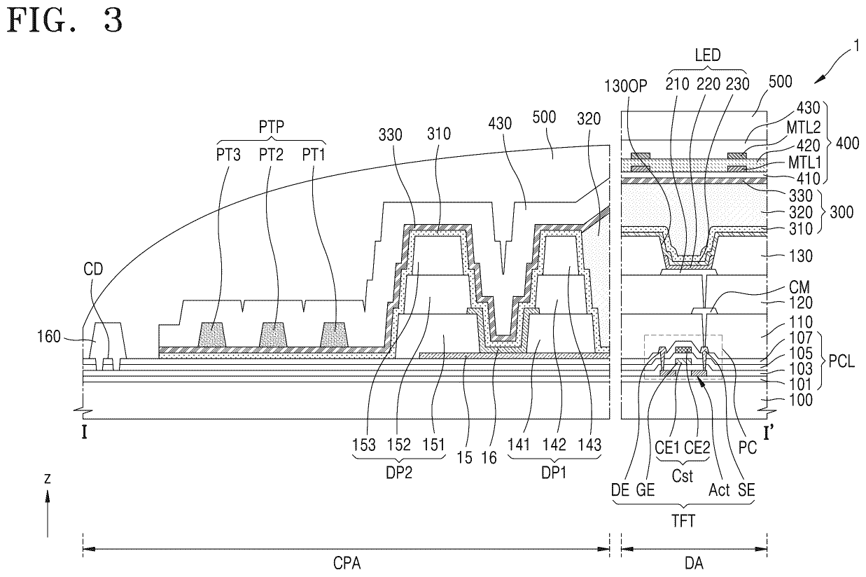

FIG. 1 is a schematic plan view of a display apparatus 1 according to an embodiment. The display apparatus 1 may include a light-emitting diode (LED) (see FIG. 3) as a display element. The display apparatus 1 may be used as a display screen for various products such as not only portable electronic devices such as mobile phones, smartphones, tablet personal computers (PCs), mobile communication terminals, electronic notebooks, e-books, portable multimedia players (PMPs), navigations, and ultra mobile PCs (UMPCs), but also televisions (TVs), laptops, monitors, billboards, Internet of Things (IoT) devices, or the like. According to an embodiment, the display apparatus 1 may also be used in wearable devices such as smart watches, watch phones, glasses-type displays, or head mounted displays (HMDs). According to an embodiment, the display apparatus 1 may also be used in dashboards of vehicles, center information displays (CIDs) of the center fascia or dashboards of vehicles, room mirror displays that replace the side view mirrors of vehicles, and display screens arranged on the rear sides of front seats to serve as entertainment devices for back seat passengers of vehicles.

Referring to FIG. 1, the display apparatus 1 may include a display area DA and a peripheral area PA located outside the display area DA. The shape of the display apparatus 1 in FIG. 1 may be substantially the same as the shape of the substrate 100. For example, describing the display apparatus 1 as including the display area DA and the peripheral area PA may indicate that the substrate 100 includes the display area DA and the peripheral area PA.

The display apparatus 1 may provide an image through an array of a plurality of pixels PX that are two-dimensionally arranged in the display area DA. Each of the pixels PX may include a pixel circuit and the display element. Each of the pixels PX may be defined as a light-emitting area through which the display element, driven by a pixel circuit, emits light. In other words, an image may be provided by light emitted by the display element through the pixels PX. An area in which the image is provided is determined by an arrangement of a plurality of display elements, and the display area DA may be defined by the plurality of display elements.

The display area DA may include a corner portion CN having an edge rounded to have a predetermined curvature. In an embodiment, the display area DA may have a rectangular shape with rounded corners. For example, the display area DA may include four sides and four corner portions CN, each of the corner portions CN located between two sides that extend in different directions. For example, the display area DA may have the corner portion CN between a side extending in a first direction (e.g., x direction) and a side extending in a second direction perpendicular to the first direction (e.g., y direction) and connecting the two sides. As used herein, a “corner” refers to a transitional area between sides that generally extend in different directions, and does not necessarily refer to an angle.

In an embodiment, the sides of the display area DA may be bent with a certain curvature. Due to the corner portion CN of the display area DA being located between adjacent sides each having a curved surface bent in different directions, the corner portion CN may include a curved surface with a curvature that would continuously connect the adjacent curved surfaces bent in multiple directions.

The display apparatus 1 may have a short side in the first direction (e.g., the x direction) and a long side in the second direction (e.g., the y direction). In an embodiment, a length of a side of the display apparatus 1 in the first direction (e.g., the x direction) may be the same as a length of a side of the display apparatus 1 in the second direction (e.g., the y direction). In an embodiment, the display apparatus 1 may have a long side in the first direction (e.g., the x direction) and a short side in the second direction (e.g., the y direction).

The peripheral area PA is an area that does not provide an image, and the pixels PX may not be located in the peripheral area PA. In other words, the peripheral area PA may be a non-display area that does not display images. The peripheral area PA may be located outside the display area DA and may be referred to as an outer area. The peripheral area PA may partially or entirely surround the display area DA. A driver or components that provide electrical signals or power to the display area DA may be arranged in the peripheral area PA.

The peripheral area PA may include a first side peripheral area SPA1, a second side peripheral area SPA2, a third side peripheral area SPA3, and a fourth side peripheral area SPA4 disposed on the sides of the display area DA, respectively. The first side peripheral area SPA1 and the fourth side peripheral area SPA4 may be disposed on opposite sides of the display area DA, with the display area DA therebetween. Each of the first side peripheral area SPA1 and the fourth side peripheral area SPA4 may extend in the first direction (e.g., x direction). The second side peripheral area SPA2 and the third side peripheral area SPA3 are disposed on opposite sides of the display area DA, with the display area DA therebetween. Each of the second side peripheral area SPA2 and the third side peripheral area SPA3 may extend in the second direction (e.g., y direction).

The peripheral area PA may include a corner peripheral area CPA located at a corner of the display apparatus 1 and having a certain curvature. In an embodiment, the peripheral area PA may include four corner peripheral areas CPA. The four corner peripheral areas CPA may be located adjacent to the four corner portions CN of the display area DA, respectively. The corner peripheral area CPA may be located between adjacent side peripheral areas SPA. For example, the corner peripheral areas CPA may be located between the first side peripheral area SPA1 and the second side peripheral area SPA2, between the first side peripheral area SPA1 and the third side peripheral area SPA3, between the second side peripheral area SPA2 and the fourth side peripheral area SPA4, and between the third side peripheral area SPA3 and the fourth side peripheral area SPA4, respectively. The corner peripheral area CPA may connect adjacent side peripheral areas SPA. For example, the corner peripheral area CPA may connect the first side peripheral area SPA1 to the second side peripheral area SPA2.

The first to fourth side peripheral areas SPA1, SPA2, SPA3, and SPA4 are not limited to being straight, and may each include a curved surface that has a curvature. For example, the first side peripheral area SPA1 and the fourth side peripheral area SPA4 may have a curved surface that curves around a bending axis extending in the x direction, and the second side peripheral area SPA2 and the third side peripheral area SPA3 may have a curved surface that curves around a bending axis extending in the y direction. The corner peripheral area CPA is located between adjacent side peripheral areas SPA with surfaces curved in different directions. Hence, the corner peripheral area CPA may include a surface that continuously curves and connects the adjacent curved surfaces that curve in multiple directions.

The peripheral area PA may further include a pad area PADA extending from the first side peripheral area SPA1 in the second direction (e.g., y direction). A pad (not shown) may be located in the pad area PADA. The pixels PX of the display apparatus 1 may receive an electrical signal and/or power voltage through the pad disposed in the pad area PADA.

The display apparatus 1 may include a first dam portion DP1 and a second dam portion DP2, each located in the peripheral area PA. Each of the first dam portion DP1 and the second dam portion DP2 may be arranged to surround the display area DA. The first dam portion DP1 and the second dam portion DP2 may be arranged spaced apart from each other. The second dam portion DP2 may be located outside the first dam portion DP1. For example, the first dam portion DP1 may be located between the second dam portion DP2 and the display area DA. Although the present embodiment shows the number of dam portions surrounding the display area DA as two, this is not a limitation of the disclosure, and the number of dam portions may be changed to one or more. The first dam portion DP1 and the second dam portion DP2 may serve as a dam that blocks an organic material from flowing toward an edge of the substrate 100 when an organic encapsulation layer 320 (see FIG. 3) constituting an encapsulation layer 300 (see FIG. 3) is formed, and thus, may prevent or reduce formation of an edge tail of the organic encapsulation layer 320 at the edge of the substrate 100.

In an embodiment, the display apparatus 1 may further include a crack prevention dam CD located in the peripheral area PA. In an embodiment, the crack prevention dam CD may surround the display area DA. In an embodiment, the crack prevention dam CD may surround the display area DA, and may have some discontinuous sections. The crack prevention dam CD may be located outside the first dam portion DP1 and the second dam portion DP2. For example, the first dam portion DP1 may be located between the crack prevention dam CD and the display area DA, and the second dam portion DP2 may be located between the crack prevention dam CD and the first dam portion DP1. In an embodiment, the crack prevention dam CD may be omitted.

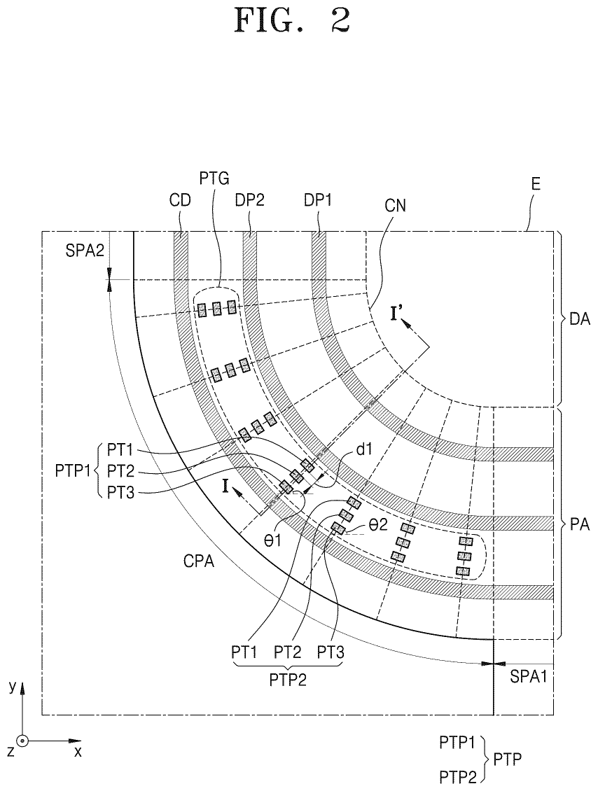

FIG. 2 is a schematic plan view of the display apparatus 1 according to an embodiment, which corresponds to an enlarged plan view of the region E of FIG. 1.

Referring to FIG. 2, a pattern group PTG including a plurality of patterns may be located in the corner peripheral area CPA. The pattern group PTG may be arranged along the rounded edge of the corner peripheral area CPA. The pattern group PTG may be located outside the second dam portion DP2. For example, the pattern group PTG may be spaced farther apart from the display area DA than the first dam portion DP1 and the second dam portion DP2. For example, the pattern group PTG may surround a portion of the second dam portion DP2, which is in turn positioned to surround the first dam portion DP1 in the corner peripheral area CPA. For example, the first dam portion DP1 may be located between the display area DA and the pattern group PTG. For example, the second dam portion DP2 may be located between the first dam portion DP1 and the pattern group PTG. The pattern group PTG may be located inside the crack prevention dam CD. For example, the pattern group PTG may be located between the crack prevention dam CD and the first dam portion DP1. For example, the pattern group PTG may be located between the crack prevention dam CD and the second dam portion DP2.

In an embodiment, the pattern group PTG may include a pattern portion PTP including a plurality of patterns (also referred to as “patterned areas”) spaced apart from each other in a radial direction, separated by pattern-free areas. A “radial direction,” as used herein, is a direction that extends from the corner portion CN of the display area DA to an outer edge of the corner peripheral area CPA, like the broken lines in FIG. 2. In an embodiment, the pattern group PTG may include a plurality of pattern portions PTP spaced apart from each other along the circumferential direction of the corner peripheral area CPA. For example, as depicted in FIG. 2, the pattern group PTG may include a first pattern portion PTP1 and a second pattern portion PTP2 spaced apart from each other along the circumferential direction of the corner peripheral area CPA. The “circumferential direction,” as used herein, is a direction that follows the curved edge of the corner peripheral area CPA by maintaining a constant distance from the edge. Each of the first pattern portion PTP1 and the second pattern portion PTP2 may include a first pattern PT1, a second pattern PT2, and a third pattern PT3 spaced apart from each other along a radial direction. One pattern of the first pattern portion PTP1 and the corresponding pattern of the second pattern portion PTP2 may be arranged along the circumferential direction of the corner peripheral area CPA. For example, the first pattern PT1 of the first pattern portion PTP1 and the first pattern PT1 of the second pattern portion PTP2 may be arranged along the circumferential direction of the corner peripheral area CPA, the second pattern PT2 of the first pattern portion PTP1 and the second pattern PT2 of the second pattern portion PTP2 may be arranged along the circumferential direction of the corner peripheral area CPA, and the third pattern PT3 of the first pattern portion PTP1 and the third pattern PT3 of the second pattern portion PTP2 may be arranged along the circumferential direction of the corner peripheral area CPA. Similarly, the pattern-free areas between the first pattern PT1, second pattern PT2, and third pattern PT3 of the first pattern portion PTP1 and the second pattern portion PTP2 may be arranged along the circumferential direction of the corner peripheral area CPA. In FIG. 2, the number of patterns included in each pattern portion PTP is shown as three. However, this is not a limitation of the disclosure, and each pattern portion PTP may include two or more patterns.

In an embodiment, the minimum separation distance between the plurality of patterns provided in one pattern portion PTP may be about 0.1 μm to about 30 μm. For example, a separation distance d1 between the first pattern PT1 and the second pattern PT2 of the first pattern portion PTP1 may be about 0.1 μm to about 30 μm. If the minimum separation distance between the plurality of patterns exceeds 30 μm, it may be difficult to form a plurality of patterns within a pattern portion PTP to keep the area of a passivation layer 430 (see FIG. 3) small, and the risk of delamination between the passivation layer 430 (see FIG. 3) and an upper organic layer 500 (see FIG. 3) may increase. If the minimum separation distance between the plurality of patterns is less than 0.1 μm, it may be challenging to form a plurality of patterns.

As depicted in FIG. 2, the first to third patterns PT1, PT2, and PT3 of the second pattern portion PTP2 may be spaced apart from the first to third patterns PT1, PT2, and PT3 of the first pattern portion PTP1 along the circumferential direction of the corner peripheral area CPA. As the first pattern portion PTP1 and the second pattern portion PTP2 are arranged along the circumferential direction of the corner peripheral area CPA, in a plan view, corresponding sides of the first pattern portion PTP1 and the second pattern portion PTP2 may be oriented in non-parallel directions. For example, a side surface of the third pattern PT3 of the first pattern portion PTP1 along the radial direction may form a first angle θ1 with respect to a first imaginary straight line extending in the first direction (e.g., x direction), and a side surface of the third pattern PT3 of the second pattern portion PTP2 along the radial direction may form a second angle θ2 with respect to a second imaginary straight line extending in the first direction (e.g., x direction). Based on the relative positions of the first pattern portion PTP1 and the second pattern portion PTP2, the second angle θ2 may be greater than the first angle θ1.

Referring to FIGS. 2 and 3, the plurality of patterns of the pattern portion PTP are embossed patterns. In an embodiment, each of the plurality of patterns of the pattern portion PTP may be an embossed pattern. In another embodiment, an arrangement of the plurality of patterns of the pattern portion PTP is the same as those described with reference to FIG. 2 and FIG. 3, but each of the plurality of patterns of the pattern portion PTP may be an engraved pattern.

FIG. 3 is a schematic cross-sectional view of a display apparatus 1 according to an embodiment, taken along line I-I′ of FIG. 2.

Referring to FIG. 3, the display apparatus 1 may include a substrate 100, a pixel circuit layer PCL, a light-emitting diode LED, an encapsulation layer 300, a touch sensor layer 400, and an upper organic layer 500.

In an embodiment, the substrate 100 may include glass. In an embodiment, the substrate 100 may include a polymer resin such as polyethersulfone, polyarylate, polyetherimide, polyethylene naphthalate, polyethylene terephthalate, polyphenylene sulfide, polyimide, polycarbonate, cellulose triacetate, or cellulose acetate propionate. In an embodiment, the substrate 100 may have a multi-layer structure including a base layer and a barrier layer (not shown), the base layer including the polymer resin described above. Hereinafter, a detailed description is given focusing on the case where the substrate 100 includes glass.

The pixel circuit layer PCL may be disposed on the substrate 100. The pixel circuit layer PCL may include a pixel circuit PC including a buffer layer 101, a first inorganic insulating layer 103, a second inorganic insulating layer 105, a third inorganic insulating layer 107, and a thin film transistor TFT. The pixel circuit PC may include at least one thin film transistor TFT and a storage capacitor Cst. The thin film transistor TFT may include a semiconductor layer Act, a gate electrode GE, a source electrode SE, and a drain electrode DE.

The buffer layer 101 may be disposed on the substrate 100, may flatten an upper surface of the substrate 100, and may reduce or block impurities from the substrate 100. The buffer layer 101 may include an inorganic insulating material such as silicon oxide (SiOₓ), silicon nitride (SiNₓ), or silicon oxynitride (SiOₓN_{y}). The buffer layer 101 may include a single-layer or multi-layer structure including the above-described inorganic insulating material.

The semiconductor layer Act may be disposed on the buffer layer 101. The semiconductor layer Act may include an oxide semiconductor and/or a silicon semiconductor. When the semiconductor layer Act includes an oxide semiconductor, the semiconductor layer Act may include an oxide of at least one selected from a group consisting of, for example, indium (In), gallium (Ga), tin (Sn), zirconium (Zr), vanadium (V), hafnium (Hf), cadmium (Cd), germanium (Ge), chromium (Cr), titanium (Ti), and zinc (Zn). For example, the semiconductor layer Act may be an InSnZnO (ITZO) semiconductor layer, an InGaZnO (IGZO) semiconductor layer, or the like. When the semiconductor layer Act includes a silicon semiconductor, the semiconductor layer Act may include, for example, amorphous silicon or low-temperature poly-silicon (LTPS).

The gate electrode GE may be disposed on the semiconductor layer Act with the first inorganic insulating layer 103 therebetween. The gate electrode GE may overlap a channel region of the semiconductor layer Act. The gate electrode GE may include a low-resistance metal material. For example, the gate electrode GE may include metal such as aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu). The gate electrode GE may include a single layer or multi-layer including the above-described metal. The gate electrode GE may be connected to a gate line that applies an electrical signal to the gate electrode GE.

The first inorganic insulating layer 103 may be disposed on the buffer layer 101. The first inorganic insulating layer 103 may be disposed between the semiconductor layer Act and the gate electrode GE. The first inorganic insulating layer 103 may include an inorganic insulating material, such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO or ZnO₂).

The second inorganic insulating layer 105 may be disposed on the first inorganic insulating layer 103. The second inorganic insulating layer 105 may cover the gate electrode GE. Similarly to the first inorganic insulating layer 103, the second inorganic insulating layer 105 may include an inorganic insulating material, such as silicon oxide (SiOₓ), silicon nitride (SiNₓ), silicon oxynitride (SiOₓN_{y}), aluminum oxide (Al₂O₃), and titanium oxide (TiO₂), tantalum oxide (Ta₂O₅), hafnium oxide (HfO₂), or zinc oxide (ZnO or ZnO₂).

An upper electrode CE2 of the storage capacitor Cst may be disposed on the second inorganic insulating layer 105. In an embodiment, the upper electrode CE2 of the storage capacitor Cst may overlap the gate electrode GE of the thin film transistor TFT. In this case, the gate electrode GE and the upper electrode CE2 overlapping with the second inorganic insulating layer 105 therebetween may form the storage capacitor Cst. In other words, the gate electrode GE may function as a lower electrode CE1 of the storage capacitor Cst. The storage capacitor Cst and the thin film transistor TFT may overlap each other. In another embodiment, the storage capacitor Cst and the thin film transistor TFT may not overlap each other.

The third inorganic insulating layer 107 may be disposed on the second inorganic insulating layer 105. The third inorganic insulating layer 107 may cover the upper electrode CE2 of the storage capacitor Cst. The third inorganic insulating layer 107 may include an inorganic insulating material, such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO or ZnO₂). The third inorganic insulating layer 107 may include a single layer or multi-layer including the above-described inorganic insulating material.

The source electrode SE and the drain electrode DE may each be disposed on the third inorganic insulating layer 107. The source electrode SE and the drain electrode DE may be electrically connected to the semiconductor layer Act through contact holes formed in the first inorganic insulating layer 103, the second inorganic insulating layer 105, and the third inorganic insulating layer 107. The source electrode SE and the drain electrode DE may each include a material with good conductivity. At least one of the source electrode SE and the drain electrode DE may include a conductive material including molybdenum (Mo), aluminum (Al), copper (Cu), or titanium (Ti). Each of the source electrode SE and the drain electrode DE may be a multi-layer or single layer including the above-described conductive material. In an embodiment, at least one of the source electrode SE and the drain electrode DE may have a multi-layer structure of Ti/Al/Ti.

In an embodiment, the display apparatus 1 may further include a power voltage line 15 on the pixel circuit layer PCL. The power voltage line 15 may be disposed on the third inorganic insulating layer 107. The power voltage line 15 may be located in the peripheral area PA. The power voltage line 15 may be a wire configured to transmit various signals and/or voltages provided to the pixel circuit PC. For example, the power voltage line 15 may be a common power supply voltage line that provides a common power supply voltage to each pixel PX (see FIG. 1).

The display apparatus 1 may further include at least one planarization layer disposed on the pixel circuit layer PCL. In an embodiment, the display apparatus 1 may include a first planarization layer 110 and a second planarization layer 120, both disposed on the pixel circuit layer PCL.

The first planarization layer 110 may be disposed on the pixel circuit layer PCL. The first planarization layer 110 may cover the pixel circuit PC. The first planarization layer 110 may be disposed on the third inorganic insulating layer 107. The first planarization layer 110 may be disposed on the source electrode SE and the drain electrode DE. The first planarization layer 110 may be disposed to cover the thin film transistor TFT. The second planarization layer 120 may cover a connection electrode CM, which is described below, and may be disposed on the first planarization layer 110.

Each of the first planarization layer 110 and the second planarization layer 120 may include an organic material. Each of the first planarization layer 110 and the second planarization layer 120 may include an organic insulating material such as a general-purpose polymer such as polymethylmethacrylate (PMMA) or polystyrene (PS), a polymer derivative having a phenol-based group, an acrylic polymer, an imide-based polymer, an aryl ether-based polymer, an amide-based polymers, fluorine-based polymers, a p-xylene-based polymers, a vinyl alcohol-based polymers, or a blend thereof. The first planarization layer 110 and the second planarization layer 120 may flatten an upper surface of the pixel circuit PC, thereby flattening a surface where the light-emitting diode LED is to be located.

In an embodiment, the display apparatus 1 may further include a connection electrode CM disposed on the first planarization layer 110 in the display area DA. The connection electrode CM may be disposed between the first planarization layer 110 and the second planarization layer 120. The connection electrode CM may include a conductive material such as molybdenum (Mo), aluminum (Al), copper (Cu), titanium (Ti), or the like, and may be a multi-layer or single layer including the above conductive material. In an embodiment, the connection electrode CM may have a multi-layer structure of Ti/Al/Ti. The second planarization layer 120 may be disposed on the first planarization layer 110 and may thus cover the connection electrode CM.

The light-emitting diode LED may be disposed on the pixel circuit layer PCL in the display area DA. The light-emitting diode LED may be electrically connected to the pixel circuit PC disposed between the substrate 100 and the light-emitting diode LED along a direction perpendicular to the substrate 100 (e.g., z direction). The light-emitting diode LED may be disposed on the second planarization layer 120. The light-emitting diode LED may emit red, green, blue, or white light. The light-emitting diode LED may have a stacked structure of a pixel electrode 210, an intermediate layer 220, and an opposite electrode 230.

The light-emitting diode LED may include an organic light-emitting diode including an organic emission layer. Alternatively, the light-emitting diode LED may include an inorganic light-emitting diode including an inorganic emission layer. The size of the light-emitting diode LED may be micro scale or nano scale. For example, the light-emitting diode LED may be a micro light-emitting diode. Alternatively, the light-emitting diode LED may be a nanorod light-emitting diode. The nanorod light-emitting diode may include gallium nitride (GaN). In an embodiment, a color conversion layer may be disposed on the nanorod light-emitting diode. The color conversion layer may include quantum dots. Alternatively, the light-emitting diode LED may include a quantum dot light-emitting diode including a quantum dot emission layer.

The pixel electrode 210 may be disposed on the second planarization layer 120. The pixel electrode 210 may be electrically connected to the connection electrode CM through a contact hole in the second planarization layer 120. In an embodiment, the pixel electrode 210 may include a conductive oxide such as indium tin oxide (ITO), indium zinc oxide (IZO), zinc oxide (ZnO or ZnO₂), indium oxide (In₂O₃), indium gallium oxide (IGO) or aluminum zinc oxide (AZO). In an embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 210 may further include a layer including ITO, IZO, ZnO, or In₂O₃ above/below the above-described reflective layer. For example, the pixel electrode 210 may have a multi-layer structure of ITO/Ag/ITO.

A pixel-defining layer 130 having an opening 130OP exposing the central portion of the pixel electrode 210 may be disposed on the pixel electrode 210. The pixel-defining layer 130 may include an organic insulating material and/or an inorganic insulating material. One opening 130OP of the pixel-defining layer 130 may correspond to one light-emitting diode LED and may define one light-emitting area. An area exposed by the opening 130OP of the pixel-defining layer 130 may be defined as a light-emitting area.

The intermediate layer 220 may be disposed on the pixel-defining layer 130. The intermediate layer 220 may include an emission layer disposed in the opening 130OP of the pixel-defining layer 130. The emission layer may include a polymer or low-molecular weight organic material that emits light of a color.

Although not shown in FIG. 3, a first functional layer and a second functional layer may be further disposed below and above the emission layer, respectively. For example, the first functional layer may include a hole transport layer (HTL), or may include an HTL and a hole injection layer (HIL). The second functional layer may be optionally disposed on the emission layer. The second functional layer may include an electron transport layer (ETL) and/or an electron injection layer (EIL). In an embodiment, the first functional layer and/or the second functional layer may be a common layer formed to entirely cover the substrate 100, similar to the opposite electrode 230, which is described below.

The opposite electrode 230 may include a conductive material with a low work function. For example, the opposite electrode 230 may include a transparent layer (or a semitransparent layer) including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 230 may further include a layer including ITO, IZO, ZnO, or In₂O₃ on the transparent layer (or the semitransparent layer) including the above-mentioned material.

In some embodiments, a capping layer (not shown) may be further disposed on the opposite electrode 230. The capping layer may include LiF, inorganic material, or/and organic material.

The encapsulation layer 300 may encapsulate the light-emitting diode LED in the display area DA. The encapsulation layer 300 may be disposed on the opposite electrode 230 of the light-emitting diode LED to cover the light-emitting diode LED. In an embodiment, the encapsulation layer 300 may include at least one inorganic encapsulation layer and at least one organic encapsulation layer. In an embodiment, the encapsulation layer 300 is shown to include a first inorganic encapsulation layer 310, an organic encapsulation layer 320, and a second inorganic encapsulation layer 330 that are stacked.

The first inorganic encapsulation layer 310 and the second inorganic encapsulation layer 330 may be disposed in the display area DA and the peripheral area PA. The first inorganic encapsulation layer 310 and the second inorganic encapsulation layer 330 may be spaced apart from each other in the display area DA. The first inorganic encapsulation layer 310 and the second inorganic encapsulation layer 330 may be spaced apart from each other in a part of the peripheral area PA and may be arranged to contact each other in the other part of the peripheral area PA. In an embodiment, the first inorganic encapsulation layer 310 and the second inorganic encapsulation layer 330 may contact each other on the first dam portion DP1 and/or the second dam portion DP2. The first inorganic encapsulation layer 310 and the second inorganic encapsulation layer 330 may be disposed above the first dam portion DP1 and the second dam portion DP2. In an embodiment, the first inorganic encapsulation layer 310 and the second inorganic encapsulation layer 330 may contact each other in an area overlapping the pattern portion PTP. The first inorganic encapsulation layer 310 and the second inorganic encapsulation layer 330 may be disposed below the pattern portion PTP.

The first inorganic encapsulation layer 310 and the second inorganic encapsulation layer 330 may include an inorganic material. Each of the first inorganic encapsulation layer 310 and the second inorganic encapsulation layer 330 may include one or more inorganic materials such as aluminum oxide (Al₂O₃), titanium oxide (TiO₂), tantalum oxide (Ta₂O₅), hafnium oxide (HfO₂), zinc oxide (ZnO or ZnO₂), silicon oxide (SiOₓ), silicon nitride (SiNₓ), or silicon oxynitride (SiOₓN_{y}).

The organic encapsulation layer 320 may be disposed in the display area DA. The organic encapsulation layer 320 may extend from the display area DA to the peripheral area PA. In an embodiment, the organic encapsulation layer 320 may extend from the display area DA to the area inside of the first dam portion DP1. The organic encapsulation layer 320 may stop at the first dam portion DP1, thereby not being present between the first dam portion DP1 and the second dam portion DP2. The organic encapsulation layer 320 may not be present outside the first dam portion DP1, and does not overlap with the second dam portion DP2. The organic encapsulation layer 320 may not contact the pattern portion PTP included in the pattern group PTG (see FIG. 2).

The organic encapsulation layer 320 may include a polymer-based material. The polymer-based material may include acrylic resin, epoxy resin, polyimide, polyethylene, or the like. In an embodiment, the organic encapsulation layer 320 may include acrylate.

The touch sensor layer 400 may be disposed on the encapsulation layer 300 in the display area DA. The touch sensor layer 400 may detect external inputs applied from the outside. The external inputs may include any input means capable of providing a change in capacitance. For example, the touch sensor layer 400 may detect input from both active-type input means that provide a driving signal and passive-type input means such as a user's body part.

The touch sensor layer 400 may include a first touch insulating layer 410, a first touch conductive layer MTL1, a second touch insulating layer 420, a second touch conductive layer MTL2, and a passivation layer 430.

The first touch insulating layer 410 may be disposed on the encapsulation layer 300. The first touch insulating layer 410 may include an inorganic material or an organic material and may be provided as a single layer or multiple layers. The first touch insulating layer 410 may prevent or reduce damage to the encapsulation layer 300 and may block interference signals that may occur when the touch sensor layer 400 is driven.

For example, each of the first touch conductive layer MTL1 and the second touch conductive layer MTL2 may have a single-layer structure or a stacked multi-layer structure. A single-layered touch conductive layer may include a metal layer or a transparent conductive layer. The metal layer may include molybdenum (Mo), silver (Ag), titanium (Ti), copper (Cu), aluminum (Al), or alloys thereof. The transparent conductive layer may include a transparent conductive oxide such as indium tin oxide (ITO), indium zinc oxide (IZO), zinc oxide (ZnO), or indium tin zinc oxide (ITZO). The transparent conductive layer may include conductive polymers such as poly(3,4-ethylenedioxythiophene) (PEDOT), metal nanowires, graphene, or the like.

A multi-layered touch conductive layer may include multiple metal layers. The multiple metal layers may have, for example, a three-layer structure of Ti/Al/Ti. The multi-layered touch conductive layer may include at least one metal layer and at least one transparent conductive layer.

In an embodiment, each of the first touch conductive layer MTL1 and the second touch conductive layer MTL2 may include a plurality of patterns. It may be understood that the first touch conductive layer MTL1 includes first conductive patterns, and the second touch conductive layer MTL2 includes second conductive patterns. The first conductive patterns and the second conductive patterns may form a touch sensor.

The first touch conductive layer MTL1 may be disposed on the first touch insulating layer 410. The second touch insulating layer 420 may be disposed on the first touch insulating layer 410 and cover the first touch conductive layer MTL1. The second touch conductive layer MTL2 may be disposed on the second touch insulating layer 420. The first touch conductive layer MTL1 may be electrically connected to the second touch conductive layer MTL2 through a contact hole passing through the second touch insulating layer 420. In an embodiment, each of the first touch conductive layer MTL1 and the second touch conductive layer MTL2 may have a mesh structure to allow light emitted from the light-emitting diode LED to pass through. In this case, each of the first touch conductive layer MTL1 and the second touch conductive layer MTL2 may be arranged to avoid overlapping the light-emitting area.

The second touch insulating layer 420 may include an organic material. The organic material may include at least one material selected from a group consisting of acrylic resin, methacrylic resin, polyisoprene, vinyl resin, epoxy resin, urethane resin, cellulose resin, and perylene resin. The second touch insulating layer 420 may further include an inorganic material. The inorganic material may include at least one material selected from the group including silicon nitride (SiNₓ), aluminum nitride (AlN), zirconium nitride (ZrN), titanium nitride (TiN), hafnium nitride (HfN), tantalum nitride (TaN), silicon oxide (SiOₓ), and aluminum oxide (Al₂O₃), titanium oxide (TiO₂), tin oxide (SnO₂), cerium oxide (CeO₂), and silicon oxynitride (SiOₓN_{y}).

The passivation layer 430 may be disposed on the second touch conductive layer MTL2. The passivation layer 430 may be disposed to cover the second touch conductive layer MTL2. The passivation layer 430 may extend from the display area DA to the peripheral area PA. The passivation layer 430 may overlap the first dam portion DP1 and the second dam portion DP2. The passivation layer 430 may be disposed on the plurality of patterns (e.g., the first to third patterns PT1, PT2, and PT3) of the pattern portion PTP. The passivation layer 430 may overlap the plurality of patterns (e.g., the first to third patterns PT1, PT2, and PT3) of the pattern portion PTP. The passivation layer 430 may be disposed above the first dam portion DP1, the second dam portion DP2, and the pattern portion PTP. The passivation layer 430 may have a single-layer or multi-layer structure. The passivation layer 430 may include an organic material, an inorganic material, or an organic-inorganic composite material.

The upper organic layer 500 may be disposed on the touch sensor layer 400. The upper organic layer 500 may be disposed on the passivation layer 430. The upper organic layer 500 is disposed in the display area DA and may extend from the display area DA to the peripheral area PA. The upper organic layer 500 may be entirely disposed on the display area DA and the peripheral area PA. The upper organic layer 500 may overlap the first dam portion DP1, the second dam portion DP2, and the pattern portion PTP. The upper organic layer 500 may overlap with a crack prevention dam CD. The upper organic layer 500 may be disposed to contact the passivation layer 430 without delamination in an area overlapping the pattern portion PTP.

In an embodiment, an area of the passivation layer 430 may increase by including a pattern portion PTP including a plurality of patterns in the corner peripheral area CPA having a curved surface. Accordingly, delamination between the passivation layer 430 and the upper organic layer 500 due to impact or deformation in the corner peripheral area CPA may be prevented or reduced.

The upper organic layer 500 may be formed through an inkjet process. The upper organic layer 500 may include an organic material. For example, the upper organic layer 500 may include a polymer-based material. The polymer-based material may include acrylic resin, epoxy resin, polyimide, polyethylene, or the like. In an embodiment, the upper organic layer 500 may include acrylate.

The display apparatus 1 may include a first dam portion DP1 and a second dam portion DP2 disposed in the peripheral area PA. The first dam portion DP1 and the second dam portion DP2 may at least partially overlap the power voltage line 15. The second dam portion DP2 may be spaced apart from the organic encapsulation layer 320 with the first dam portion DP1 therebetween. In other words, the first dam portion DP1 may be disposed between the second dam portion DP2 and the organic encapsulation layer 320.

The first dam portion DP1 may include a first dam pattern 141, a second dam pattern 142, and a third dam pattern 143 that are stacked. The first dam pattern 141 may be disposed on the third inorganic insulating layer 107. The first dam pattern 141 may be formed in the same process operation as the first planarization layer 110, and may include the same material as that of the first planarization layer 110. The second dam pattern 142 may be disposed on the first dam pattern 141. The second dam pattern 142 may be formed in the same process operation as the second planarization layer 120, and may include the same material as that of the second planarization layer 120. The third dam pattern 143 may be disposed on the second dam pattern 142. The third dam pattern 143 may be formed in the same process operation as the pixel-defining layer 130, and may include the same material as that of the pixel-defining layer 130.

The second dam portion DP2 may include a fourth dam pattern 151, a fifth dam pattern 152, and a sixth dam pattern 153 that are stacked. The fourth dam pattern 151 may be disposed on the third inorganic insulating layer 107. The fourth dam pattern 151 may be formed in the same process operation as the first planarization layer 110, and may include the same material as that of the first planarization layer 110. The fifth dam pattern 152 may be disposed on the fourth dam pattern 151. The fifth dam pattern 152 may be formed in the same process operation as the second planarization layer 120, and may include the same material as that of the second planarization layer 120. The sixth dam pattern 153 may be disposed on the fifth dam pattern 152. The sixth dam pattern 153 may be formed in the same process operation as the pixel-defining layer 130, and may include the same material as that of the pixel-defining layer 130.

The number and height of dam patterns included in the first dam portion DP1 and the second dam portion DP2 are not limited to those shown and may vary according to one or more embodiments.

A portion of the power voltage line 15 may be disposed between the first dam pattern 141 of the first dam portion DP1 and the fourth dam pattern 151 of the second dam portion DP2. In an embodiment, the fourth dam pattern 151 of the second dam portion DP2 may cover an edge of the power voltage line 15. In an embodiment, a portion of the power voltage line 15 between the first dam portion DP1 and the second dam portion DP2 may not be covered by the first dam portion DP1 and the second dam portion DP2. A conductive pattern 16 may be further disposed on an upper surface of a portion of the power voltage line 15 that is exposed and does not overlap the first dam portion DP1 and the second dam portion DP2. In an embodiment, the conductive pattern 16 may be disposed on a side surface and a portion of an upper surface of the first dam pattern 141, the upper surface of the power voltage line 15, and a side surface and a portion of an upper surface of the fourth dam pattern 151.

Due to the pattern portion PTP included in the pattern group PTG (see FIG. 2) being disposed outside the first dam portion DP1 and the second dam portion DP2, delamination between the passivation layer 430 and the upper organic layer 500 at an edge region (or edge area) of the corner peripheral area CPA may be prevented or reduced. The plurality of patterns (e.g., first to third patterns PT1, PT2, and PT3) of the pattern portion PTP may be disposed above the first inorganic encapsulation layer 310 and the second inorganic encapsulation layer 330.

In an embodiment, when each of the plurality of patterns (e.g., the first to third patterns PT1, PT2, and PT3) of the pattern portion PTP is formed as an embossed pattern, as shown in FIGS. 2 and 3, the patterns may include organic materials. In an embodiment, the plurality of patterns (e.g., the first to third patterns PT1, PT2, and PT3) of the pattern portion PTP may be formed using the same process operations as those used to form an organic layer disposed below the passivation layer 430 of the touch sensor layer 400 in the display area DA. For example, the plurality of patterns (e.g., first to third patterns PT1, PT2, and PT3) of the pattern portion PTP may be formed using the same process operations as those used to form the second touch insulating layer 420 between the first touch conductive layer MTL1 and the second touch conductive layer MTL2, and may include the same material as that of the second touch insulating layer 420. In another embodiment, the plurality of patterns may be formed by an inkjet printing process separate from an operation of forming the layers disposed in the display area DA. The plurality of patterns are shown as a single layer, but one or more embodiments are not limited thereto and the plurality of patterns may be multiple layers. A height of the plurality of patterns is not limited to that shown and may vary.

The crack prevention dam CD may be disposed at an end or edge region of the substrate 100. The crack prevention dam CD may be placed at the end or edge region of the corner peripheral area CPA. The crack prevention dam CD may be disposed outside the first dam portion DP1, the second dam portion DP2, and the pattern portion PTP.

The crack prevention dam CD may have various shapes, may be formed of the same material as that of some of the components formed in the display area DA, and may also have a multi-layer structure. FIG. 3 shows that the crack prevention dam CD includes two layers. For example, the crack prevention dam CD may include a lower layer including the same material as that of the second inorganic insulating layer 105 and an upper layer including the same material as that of the third inorganic insulating layer 107. The crack prevention dam CD may be understood as being formed by removing part of the second inorganic insulating layer 105 and the third inorganic insulating layer 107. However, the structure of the crack prevention dam CD is not limited thereto, and may be a structure including two or more layers. For example, the buffer layer 101, the first inorganic insulating layer 103, the second inorganic insulating layer 105, and the third inorganic insulating layer 107 may be partially removed to form a four-layer structure. The crack prevention dam CD is shown as a single one, but is not limited thereto and may include multiple crack prevention dams that are spaced apart.

The crack prevention dam CD may be covered with a cover layer 160. The cover layer 160 may be a layer including an organic material that covers a crack prevention dam CD including an inorganic material. The cover layer 160 may cover the crack prevention dam CD and may fill an area from which parts of the second inorganic insulating layer 105 and the third inorganic insulating layer 107 are removed.

One or more embodiments described below are modified embodiments of the embodiment described with reference to FIGS. 2 and 3, and the description will focus on the modified parts, and redundant descriptions will be omitted or simplified.

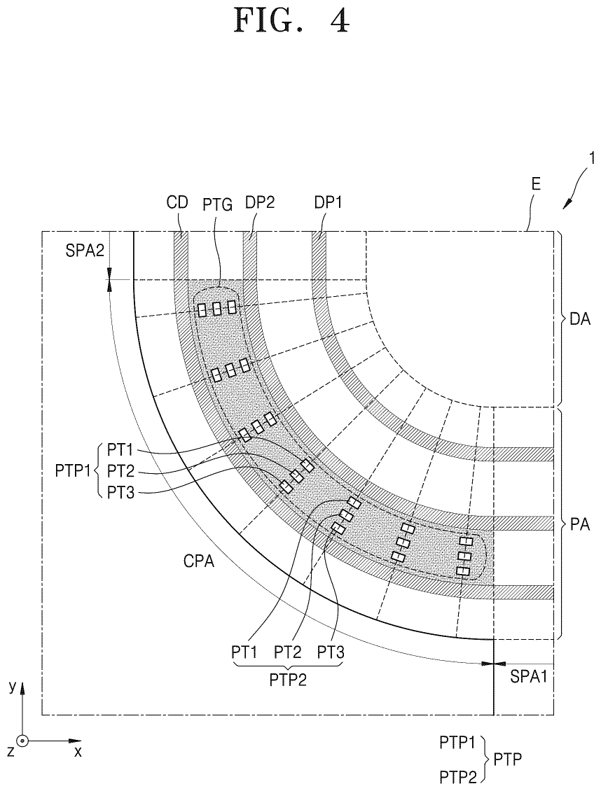

FIG. 4 is a schematic plan view of the display apparatus 1 according to an embodiment, which corresponds to an enlarged plan view of the region E of FIG. 1.

Referring to FIG. 4, each of a plurality of patterns (e.g., the first to third patterns PT1, PT2, and PT3) of the pattern portion PTP may be an engraved pattern. When each of the plurality of patterns of the pattern portion PTP is an engraved pattern, the patterns (e.g., the first to third patterns PT1, PT2, and PT3) may be defined as grooves formed by removing a portion of an organic layer located outside the second dam portion DP2.

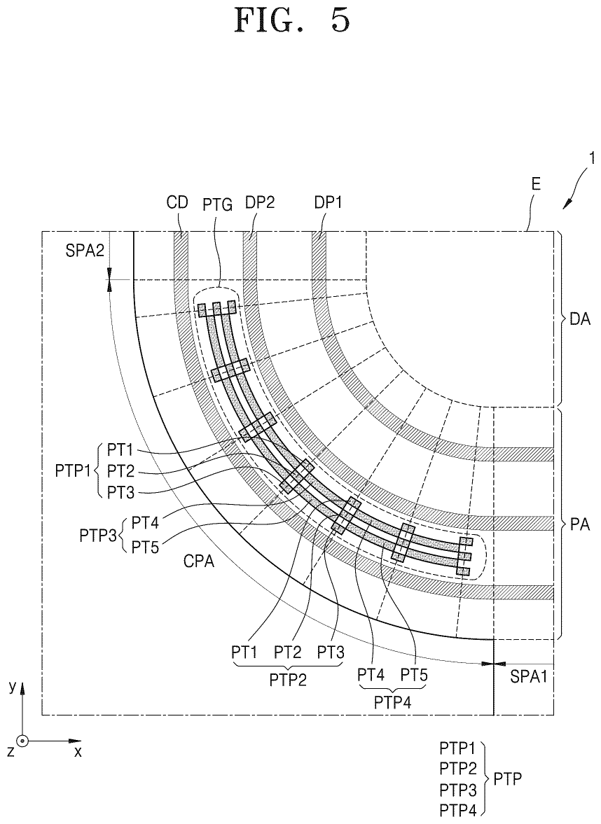

FIG. 5 is a schematic plan view of the display apparatus 1 according to an embodiment, which corresponds to an enlarged plan view of the region E of FIG. 1.

Referring to FIG. 5, the pattern group PTG may further include a third pattern portion PTP3 and a fourth pattern portion PTP4 separated from each other along the circumferential direction of the corner peripheral area CPA, for example by the second pattern portion PTP2. Each of the third pattern portion PTP3 and the fourth pattern portion PTP4 may include at least one pattern. Each of the third pattern portion PTP3 and the fourth pattern portion PTP4 may include a fourth pattern PT4 and a fifth pattern PT5 spaced apart from each other in the radial direction by pattern-free areas. One pattern of the third pattern portion PTP3 and the corresponding pattern of the fourth pattern portion PTP4 may be arranged along the circumferential direction about the same distance from the outer edge of the corner peripheral area CPA. The fourth pattern PT4 of the third pattern portion PTP3 and the fourth pattern PT4 of the fourth pattern portion PTP4 may be arranged along the circumferential direction about the same distance from the outer edge of the corner peripheral area CPA, and the fifth pattern PT5 of the third pattern portion PTP3 and the fifth pattern PT5 of the fourth pattern portion PTP4 may be arranged along the circumferential direction about the same distance from the outer edge of the corner peripheral area CPA. For the first pattern portion PTP1 and the second pattern portion PTP2, the pattern-free areas (space between the first pattern PT1, the second pattern PT2, and the third pattern PT3) are arranged about the same distance from the outer edge of the corner peripheral area CPA as the fourth pattern PT4 and the fifth pattern PT5. Each of the third pattern portion PTP3 and the fourth pattern portion PTP4 is shown as having two patterned areas, but this is an example and each of the third pattern portion PTP3 and the fourth pattern portion PTP4 may have one or more patterns.

The third pattern portion PTP3 may be located between the first pattern portion PTP1 and the second pattern portion PTP2. In an embodiment, the pattern of the third pattern portion PTP3 may have a surface curved along the circumferential direction of the corner peripheral area CPA. At least one patterned area of the third pattern portion PTP3 (e.g., the fourth pattern PT4 and the fifth pattern PT5), the patterned areas of the first pattern portion PTP1 (e.g., the first pattern PT1, the second pattern PT2, and the third pattern PT3), and the patterned areas of the second pattern portion PTP2 (e.g., the first pattern PT1, the second pattern PT2, and the third pattern PT3) may form a curved checkerboard pattern with pattern-free areas in a plan view.

The second pattern portion PTP2 may be located between the third pattern portion PTP3 and the fourth pattern portion PTP4. In an embodiment, the pattern of the fourth pattern portion PTP4 may have a surface curved along the circumferential direction of the corner peripheral area CPA. At least one patterned area of the fourth pattern portion PTP4 (e.g., the fourth pattern PT4 and the fifth pattern PT5), at least one patterned area of the third pattern portion PTP3 (e.g., the fourth pattern PT4, and the fifth pattern PT5), and the patterned areas of the second pattern portion PTP2 (e.g., the first pattern PT1, the second pattern PT2, and the third pattern PT3) may form a checkerboard pattern with pattern-free areas in a plan view.

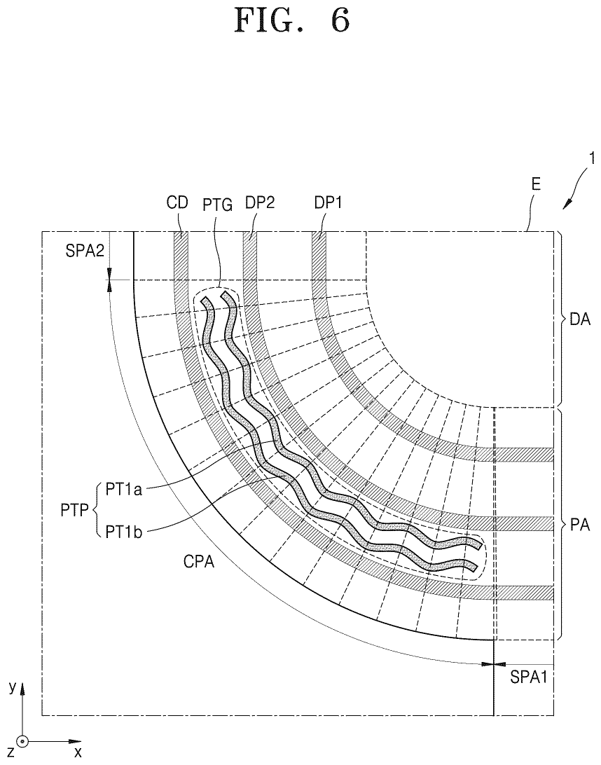

FIG. 6 is a schematic plan view of the display apparatus 1 according to an embodiment, which corresponds to an enlarged plan view of the region E of FIG. 1.

Referring to FIG. 6, the pattern group PTG may include a pattern portion PTP including a plurality of patterns spaced apart from each other in the radial direction and having a curvature. For example, the pattern portion PTP may include a first pattern PT1a and a second pattern PT1b arranged to be spaced apart from each other along the radial direction.

In an embodiment, each of the first pattern PT1a and the second pattern PT1b may have a wave shape or a zigzag shape extending along the circumferential direction of the corner peripheral area CPA in a plan view. For example, each of the first pattern PT1a and the second pattern PT1b may have a single pattern shape, which may be a wave shape or a zigzag shape with portions alternately extending toward the display area DA and the outer edge of the corner peripheral area CPA.

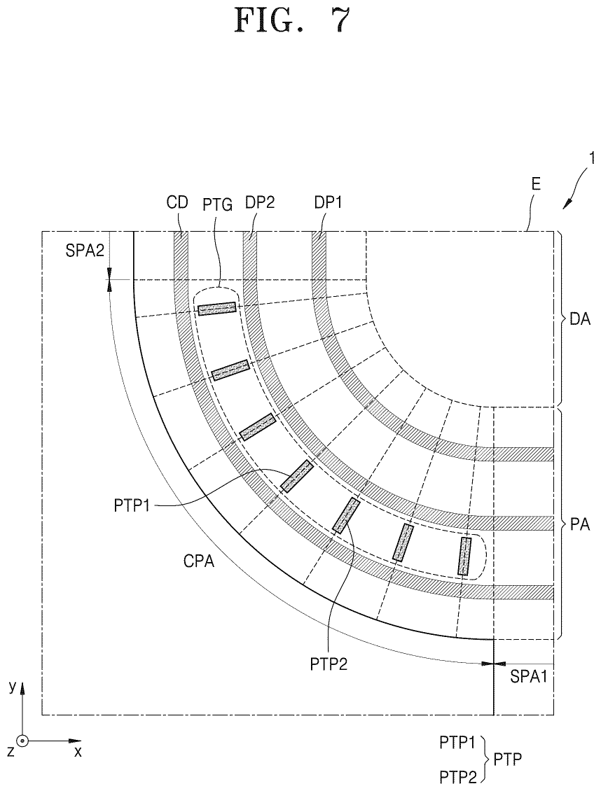

FIG. 7 is a schematic plan view of the display apparatus 1 according to an embodiment, which corresponds to an enlarged plan view of the region E of FIG. 1.

Referring to FIG. 7, the pattern group PTG may include a plurality of pattern portions PTP spaced apart from each other along the circumferential direction of the corner peripheral area CPA. For example, the pattern group PTG may include a first pattern portion PTP1 and a second pattern portion PTP2 spaced apart from each other along the circumferential direction of the corner peripheral area CPA. In an embodiment, the first pattern portion PTP1 and the second pattern portion PTP2 may be provided as a single pattern rather than including a plurality of patterns. Each of the first pattern portion PTP1 and the second pattern portion PTP2 may extend along the radial direction.

As the first pattern portion PTP1 and the second pattern portion PTP2 are arranged along the circumferential direction of the corner peripheral area CPA, corresponding parts of the first pattern portion PTP1 and the second pattern portion PTP2 may be arranged in non-parallel directions. For example, a side surface of the first pattern portion PTP1 along the radial direction may form an angle with respect to an imaginary line that extends in the first direction (e.g., x direction) that is different from the angle formed by a side surface of the second pattern portion PTP2 along the radial direction. In the example of FIG. 7, the radially-extending side surface of the second pattern portion PTP2 may form a larger angle than the radially-extending side surface of the first pattern portion PTP1 with respect to an imaginary line that extends in the first direction, due to the positions of the pattern portions.

The embodiments described with reference to FIGS. 5 to 7 are illustrated based on the patterns being embossed patterns similar to that of FIG. 2. However, this is not a limitation of the disclosure. For example, the embodiments described with reference to FIGS. 5 to 7 may be modified and applied such that the patterns are engraved patterns as described with reference to FIG. 4.

The display apparatus according to the embodiment may be applied to various electronic apparatuses. An electronic apparatus according to an embodiment of the present disclosure may include the display apparatus (e.g., the display apparatus of FIG. 1) described above, and may further include modules or apparatuses having additional functions in addition to the display apparatus.

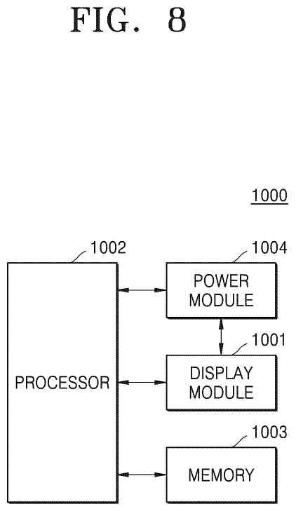

FIG. 8 is a block diagram of an electronic apparatus according to an embodiment.

Referring to FIG. 8, an electronic apparatus 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic apparatus 1000.

At least one of the components of the electronic apparatus 1000 described above may be included in the display apparatus according to the embodiments described above. In addition, a part among the individual modules functionally included in one module may be included in the display apparatus, and another part may be provided separately from the display apparatus. For example, the display apparatus may include the display module 1001, and the processor 1002, the memory 1003, and the power module 1004 may be provided in the form of other apparatuses within the electronic apparatus 1000 except for the display apparatus.

In an embodiment, the display module 1001 included in the display apparatus may drive based on the image data signal and the input control signal received from the processor 1002.

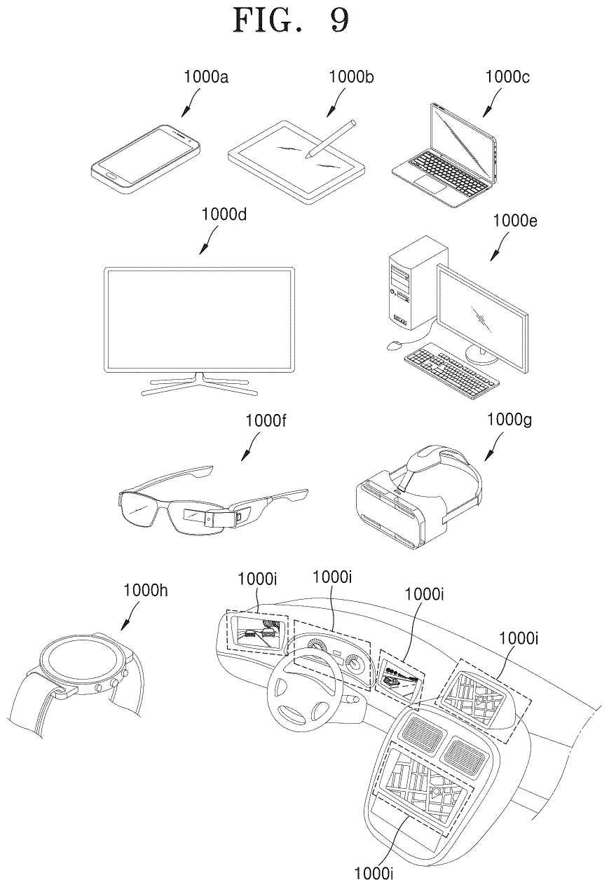

FIG. 9 is schematic diagrams of electronic apparatuses according to various embodiments.

Referring to FIG. 9, various electronic apparatuses to which display apparatuses according to embodiments are applied may include not only image display electronic apparatuses such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

According to one or more embodiments, delamination between layers disposed in the corner peripheral area of the display apparatus may be reduced or prevented by forming a plurality patterns in the corner peripheral area located outside the display area at the rounded edge.

The present embodiments have been described with reference to embodiments shown in the drawings. A person of ordinary skill in the art will understand that the embodiments presented are examples and various modifications and variations are possible. The scope of the present disclosure should be determined by the attached claims.

What is claimed is:

1. A display apparatus comprising:
a display area;
a peripheral area located outside the display area and including sides and a corner peripheral area that is curved and located between two of the sides that extend in different directions;
a display element located in the display area;
a first dam portion located in the peripheral area and arranged to surround the display area; and
a pattern group located in the corner peripheral area such that the first dam portion is between the display area and the pattern group,
wherein the pattern group includes a first pattern portion including a plurality of patterns spaced apart from each other along a radial direction.

2. The display apparatus of claim 1, wherein
the pattern group further includes a second pattern portion including a plurality of patterns spaced apart from each other in the radial direction, and
the second pattern portion is spaced apart from the first pattern portion along a circumferential direction of the corner peripheral area.

3. The display apparatus of claim 2, wherein,
corresponding parts of a pattern among the plurality of patterns of the first pattern portion and a pattern among the plurality of patterns of the second pattern portion are non-parallel.

4. The display apparatus of claim 2, wherein
the pattern group further includes a third pattern portion located between the first pattern portion and the second pattern portion and including at least one pattern, and
in a plan view, patterns of the first pattern portion, the second pattern portion, and the third pattern portion form a curved checkerboard with pattern-free areas.

5. The display apparatus of claim 1, wherein,
each of the plurality of patterns of the first pattern portion is a wave shaped pattern extending along a circumferential direction of the corner peripheral area.

6. The display apparatus of claim 1, wherein
each of the plurality of patterns of the first pattern portion is an embossed pattern.

7. The display apparatus of claim 1, wherein
each of the plurality of patterns of the first pattern portion is an engraved pattern.

8. The display apparatus of claim 1, further comprising:
a second dam portion located in the peripheral area and surrounding the display area,
wherein the second dam portion is located between the pattern group and the first dam portion.

9. The display apparatus of claim 1, further comprising
a crack prevention dam located in the peripheral area and surrounding the display area,
wherein the pattern group is located between the first dam portion and the crack prevention dam.

10. The display apparatus of claim 1, further comprising
an encapsulation layer that encapsulates the display element in the display area and includes at least one inorganic encapsulation layer and at least one organic encapsulation layer,
wherein the at least one organic encapsulation layer extends from the display area to the first dam portion located in the peripheral area.

11. The display apparatus of claim 10, wherein
the at least one organic encapsulation layer does not overlap with the pattern group.

12. The display apparatus of claim 10, wherein
the at least one inorganic encapsulation layer extends from the display area to the peripheral area, is disposed on the first dam portion and under the first pattern portion.

13. The display apparatus of claim 10, further comprising:
a touch sensor layer disposed on the encapsulation layer in the display area,
wherein the touch sensor layer comprises:
a first touch conductive layer;
a second touch conductive layer disposed on the first touch conductive layer;
a touch insulating layer between the first touch conductive layer and the second touch conductive layer; and
a passivation layer disposed on the second touch conductive layer,
wherein the passivation layer extends from the display area to the peripheral area and is disposed on the plurality of patterns of the first pattern portion.

14. The display apparatus of claim 13, wherein
each of the plurality of patterns of the first pattern portion includes a same material as the touch insulating layer.

15. A display apparatus comprising:
a display area;
a peripheral area located outside the display area and including sides and a corner peripheral area that is curved and located between two of the sides that extend in different directions;
a display element located in the display area;
a first dam portion located in the peripheral area and arranged to surround the display area; and
a pattern group located in the corner peripheral area such that the first dam portion is between the display area and the pattern group,
wherein the pattern group includes a first pattern portion and a second pattern portion spaced apart from each other along a circumferential direction of the corner peripheral area, and
each of the first pattern portion and the second pattern portion includes at least one pattern.

16. The display apparatus of claim 15, wherein
the pattern group further includes a third pattern portion located between the first pattern portion and the second pattern portion and including at least one pattern, and
in a plan view, patterns of the first pattern portion, the second pattern portion, and the third pattern portion form a curved checkerboard with pattern-free areas.

17. The display apparatus of claim 15, wherein
the at least one pattern of each of the first pattern portion and the second pattern portion is an embossed pattern.

18. The display apparatus of claim 15, wherein
the at least one pattern of each of the first pattern portion and the second pattern portion is an engraved pattern.

19. The display apparatus of claim 15, further comprising:
a second dam portion located in the peripheral area and surrounding the display area,
wherein the second dam portion is located between the pattern group and the first dam portion.

20. The display apparatus of claim 15, further comprising
an encapsulation layer that encapsulates the display element in the display area and includes at least one inorganic encapsulation layer and at least one organic encapsulation layer,
wherein the at least one organic encapsulation layer extends from the display area to the first dam portion located in the peripheral area, and
the at least one inorganic encapsulation layer extends from the display area to the peripheral area, is disposed on the first dam portion and under the first pattern portion.
